(19) United States
(12) Patent Application Publication
(10) Pub. No.: US 2013/0306130 A1
(43) Pub. Date: Nov. 21, 2013

(54) SOLAR MODULE APPARATUS WITH EDGE REFLECTION ENHANCEMENT AND METHOD OF MAKING THE SAME

(71) Applicants: Karl Reichstetter, San Francisco, CA (US); Albert S. Brown, San Jose, CA (US)

(72) Inventors: Karl Reichstetter, San Francisco, CA (US); Albert S. Brown, San Jose, CA (US)

(73) Assignee: Stion Corporation, San Jose, CA (US)

(21) Appl. No.: 13/476,573

(22) Filed: May 21, 2012

(51) Int. Cl. H01L 31/052; H01L 31/0232

(52) U.S. Cl. CPC H01L 31/0525; H01L 31/02325
USPC 136/246; 438/72

(57) ABSTRACT

A monolithic integrated solar module with edge reflection enhancement includes a plurality of thin-film photovoltaic cells formed overlying a surface region of a glass substrate except in vicinities of peripheral edge regions. The solar module further includes a mask tape applied on a conductor bar disposed within the peripheral edge regions and coupled with the plurality of thin-film photovoltaic cells and an edge seal material disposed within the peripheral edge regions in a vicinity of the mask tape and an end region of the glass substrate. Additionally, the solar module includes a top glass panel disposed overlying the plurality of thin-film photovoltaic cells, the mask tape, and the edge seal material. Moreover, the solar module includes a reflector structure comprising one or more angled surfaces being configured to facilitate scattering of incoming sunlight from the vicinities of the peripheral edge regions partially to the plurality of thin-film photovoltaic cells.

### BACKGROUND OF THE INVENTION

The present invention relates generally to techniques for the manufacture of photovoltaic devices. More particularly, the present invention provides a solar module with light reflection enhancement around peripheral edge regions and a method of making the same. Merely by way of examples, the present method is applied to integrate one or more solar modules with both external reflectors and internal reflection-enhanced edge seal materials, but it would be recognized that the invention may have other applications.

From the beginning of time, mankind has been challenged to find way of harnessing energy. Energy comes in the forms such as petrochemical, hydroelectric, nuclear, wind, biomass, solar, and more primitive forms such as wood and coal. Over the past century, modern civilization has relied upon petrochemical energy as an important energy source. Petrochemical energy includes gas and oil. Gas includes lighter forms such as butane and propane, commonly used to heat homes and serve as fuel for cooking Gas also includes gasoline, diesel, and jet fuel, commonly used for transportation purposes. Heavier forms of petrochemicals can also be used to heat homes in some places. Unfortunately, the supply of petrochemical fuel is limited and essentially fixed based upon the amount available on the planet Earth. Additionally, as more people use petroleum products in growing amounts, it is rapidly becoming a scarce resource, which will eventually become depleted over time.

More recently, environmentally clean and renewable sources of energy have been desired. An example of a clean source of energy is hydroelectric power. Hydroelectric power is derived from electric generators driven by the flow of water produced by dams such as the Hoover Dam in Nevada. The electric power generated is used to power a large portion of the city of Los Angeles in California. Clean and renewable sources of energy also include wind, waves, biomass, and the like. That is, windmills convert wind energy into more useful forms of energy such as electricity. Still other types of clean energy include solar energy. Specific details of solar energy can be found throughout the present background and more particularly below.

Solar energy technology generally converts electromagnetic radiation from the sun to other useful forms of energy. These other forms of energy include thermal energy and electrical power. For electrical power applications, solar cells are often used. Although solar energy is environmentally clean and has been successful to a point, many limitations remain to be resolved before it becomes widely used throughout the world. As an example, one type of solar cell uses crystalline materials, which are derived from semiconductor material ingots. These crystalline materials can be used to fabricate optoelectronic devices that include photovoltaic and photodiode devices that convert electromagnetic radiation into electrical power. However, crystalline materials are often costly and difficult to make on a large scale. Additionally, devices made from such crystalline materials often have low energy conversion efficiencies. Other types of solar cells use “thin film” technology to form a thin film of photosensitive material to be used to convert electromagnetic radiation into electrical power. Similar limitations exist with the use of thin film technology in making solar cells. That is, efficiencies for thin-film photovoltaic cells based on various types of absorber materials are often relatively poor. Recently, many improvements have been achieved in the manufacture of monolithic integrated thin-film solar modules formed on large glass panels with high efficiency. A plurality of thin-film photovoltaic cells are formed with nearly invisible cell lines and occupy almost the entire surface region of the glass substrate. Still there are some photo-inactive areas around peripheral edge regions of the solar module that are used for placing a module electrical bus bar and edge seal material or capped with a frame structure without being used proactively. This electrically inactive space is often covered with a frame structure. FIG. 1 shows a cross-sectional view of a typical framed thin-film solar module 10, a dark colored edge seal material and mask tape are applied in the peripheral edge regions before being capped with a top glass panel. A frame structure is wrapped around peripheral edge regions from both the bottom of the substrate and top glass panel. The frame structure itself usually is made of anodized aluminum having a flat member disposed over the peripheral edge region of the top glass panel. The flat member as well as part of dark colored mask tape, as a result of its dark color, absorbs income sunlight there without utilizing it for generating electric energy. These and other limitations of these conventional thin-film solar module manufacture techniques can be found throughout the present specification and can be improved by applying one or more embodiments of present invention described in the specification below.

### BRIEF SUMMARY OF THE INVENTION

The present invention relates generally to techniques for the manufacture of photovoltaic devices. More particularly, the present invention provides a solar module with light reflection enhancement around peripheral edge regions and a method of making the same. Merely by way of examples, the present method is applied to integrate solar modules or solar module arrays with edge reflection-enhancement, but it would be recognized that the invention may have other applications.

In a specific embodiment, the present invention provides a monolithically integrated solar module with edge reflection enhancement. The solar module includes a plurality of thin-film photovoltaic cells formed overlying a surface region of a glass substrate, except in vicinities of peripheral edge regions. The solar module further includes a mask tape applied on a conductor bar disposed within the peripheral edge regions and coupled with the plurality of thin-film photovoltaic cells. Additionally, the solar module includes an edge seal material disposed within the peripheral edge regions in a vicinity of the mask tape and an end region of the glass substrate. Furthermore, the solar module includes a top glass panel disposed overlying the plurality of thin-film photovoltaic cells, the mask tape, and the edge seal material. Moreover, the solar module includes a reflector structure comprising one or more angled surfaces each being configured to facilitate scattering of incoming sunlight from the vicinities of peripheral edge regions partially to the plurality of thin-film photovoltaic cells.

In another specific embodiment, the present invention provides a solar module with reflection enhancement on frameless edge regions. The solar module includes a plurality of photovoltaic cells formed overlying a surface region of a glass substrate except vicinities of peripheral edge regions. Additionally, the solar module includes a mask tape applied on a conductor bar disposed within the peripheral edge regions and coupled with one or more of the plurality of photovoltaic cells. Furthermore, the solar module includes an edge seal material disposed between the top glass panel and the glass substrate within the peripheral edge regions. The edge seal material is configured with the mask tape to cause incoming sunlight being substantially reflected away from the peripheral edge regions. Moreover, the solar module includes a top glass panel disposed overlying the plurality of photovoltaic cells, the mask tape, and the edge seal material. The top glass panel is configured to re-direct at least partially the reflected sunlight from the edge seal material and the mask tape back to the plurality of photovoltaic cells.

In yet another specific embodiment, the present invention provides a method for solar module lamination with enhanced edge light reflection. The method includes providing a plurality of photovoltaic cells formed overlying substantially entire surface region of a glass substrate except vicinities of peripheral edge regions. The method further includes sealing the peripheral edge regions with an edge seal material. Additionally, the method includes applying an encapsulation material over the plurality of photovoltaic cells including the edge seal material. Furthermore, the method includes disposing a top glass panel having a substantially same form factor of the glass substrate to bond with the encapsulation material. Moreover, the method includes wrapping around the top glass panel and the glass substrate by a frame structure having multiple angled-surface members disposed within the vicinities of the peripheral edge regions. The multiple angled-surface members are tilted above edge regions of the top glass panel to redirect incoming sunlight at least partially toward the plurality of photovoltaic cells.

Many benefits can be achieved by applying the embodiments of the present invention. Particularly, a monolithically integrated thin-film solar module is advantageously assembled by a frame structure with multiple angled-surface members for enhancing edge light reflection so that the photovoltaic active regions can be exposed to more sun light and is able to effectively produce solar energy with enhanced efficiency. In certain embodiments, solar modules without frames can be laminated by applying reflection enhanced edge seal material and mask tape within peripheral edge regions to replace commonly used black-colored edge seal and tape. The reflected or scattered light from the peripheral edge regions can be re-directed, at least partially, back to the photovoltaic active regions by surface of top glass panel of the laminated module or interface between the top glass panel and encapsulation material used for bonding the glass panel. In certain other embodiments, when a plurality of frameless solar modules are assembled to form a solar module array in the field, multiple reflection structures can be disposed in the boundary regions to reflect sun light there toward the module surface regions. The reflector structure can be simply clamped to part of the peripheral edge regions of each laminated solar module that is supported by an assembled mounting rack. These and other benefits may be described throughout the present specification and more particularly below.

### BRIEF DESCRIPTION OF THE DRAWINGS

FIG. 1 is a simplified cross sectional diagram of a framed solar module of prior art;

FIG. 2 is a simplified cross sectional diagram of a framed solar module with edge reflection enhancement according to an embodiment of the present invention;

FIG. 2A is a simplified diagram illustrating exemplary edge reflection of the framed solar module in FIG. 2 according to an embodiment of the present invention;

FIG. 2B is a simplified diagram showing a top view off a monolithic thin-film solar module with an edge reflection enhanced frame according to an embodiment of the present invention;

FIG. 3 is a simplified cross sectional diagram of a frameless solar module with edge reflection enhancement according to an embodiment of the present invention;

FIG. 3A is a simplified diagram illustrating exemplary edge reflection of the frameless solar module in FIG. 3 according to an embodiment of the present invention;

FIG. 4 is a schematic diagram of a solar module array with edge reflection enhancement according to an embodiment of the present invention;

FIG. 4A is an AA′ cross-sectional view of the solar module array in FIG. 4 according to an embodiment of the present invention;

FIG. 5 is a schematic flowchart illustrating a method for making a solar module with edge reflection enhancement according to an embodiment of the present invention.

### DETAILED DESCRIPTION OF THE INVENTION

The present invention relates generally to techniques for the manufacture of photovoltaic devices. More particularly, the present invention provides a solar module with light reflection enhancement around peripheral edge regions and a method of making the same. Merely by way of examples, the present method is applied to integrate solar modules or solar module array with edge reflection-enhancement, but it would be recognized that the invention may have other applications.

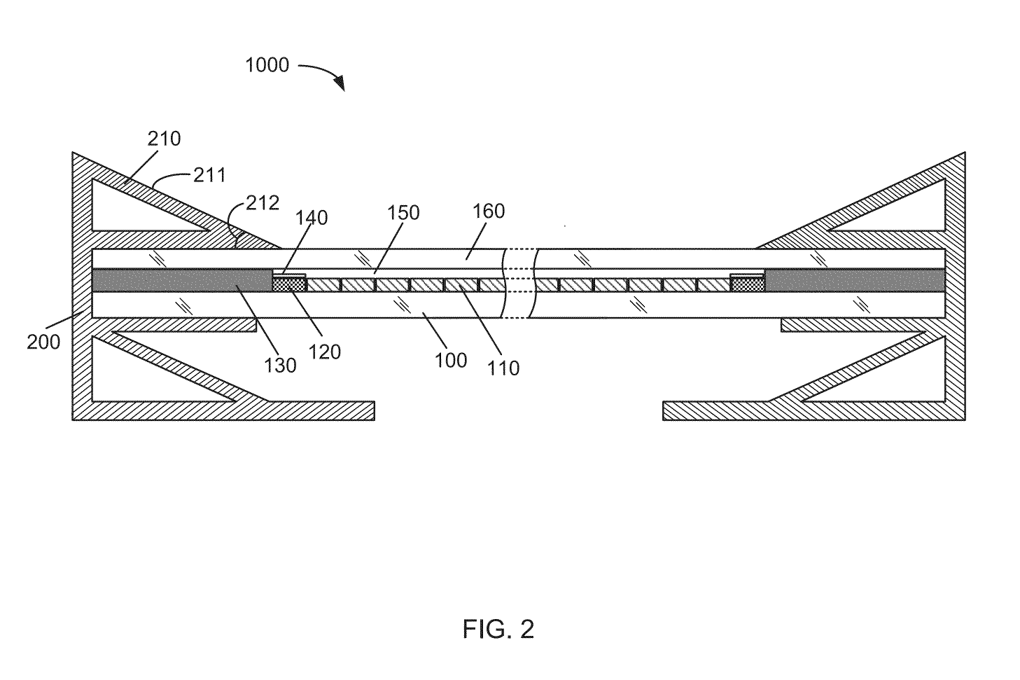

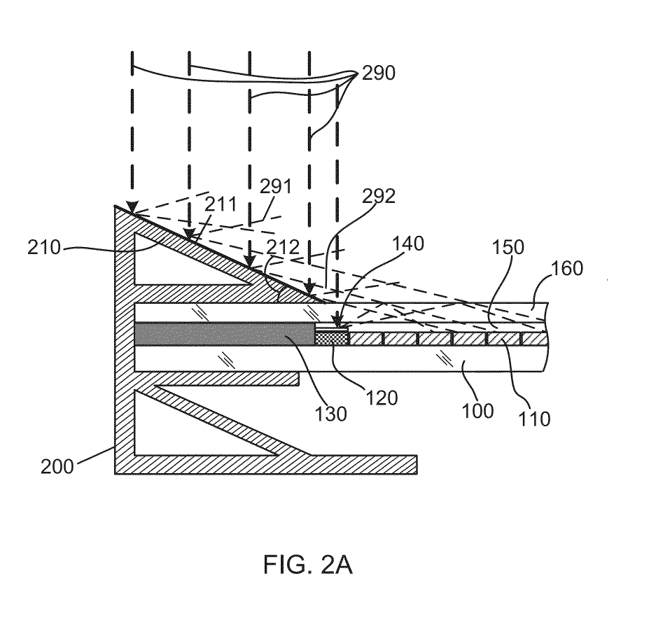

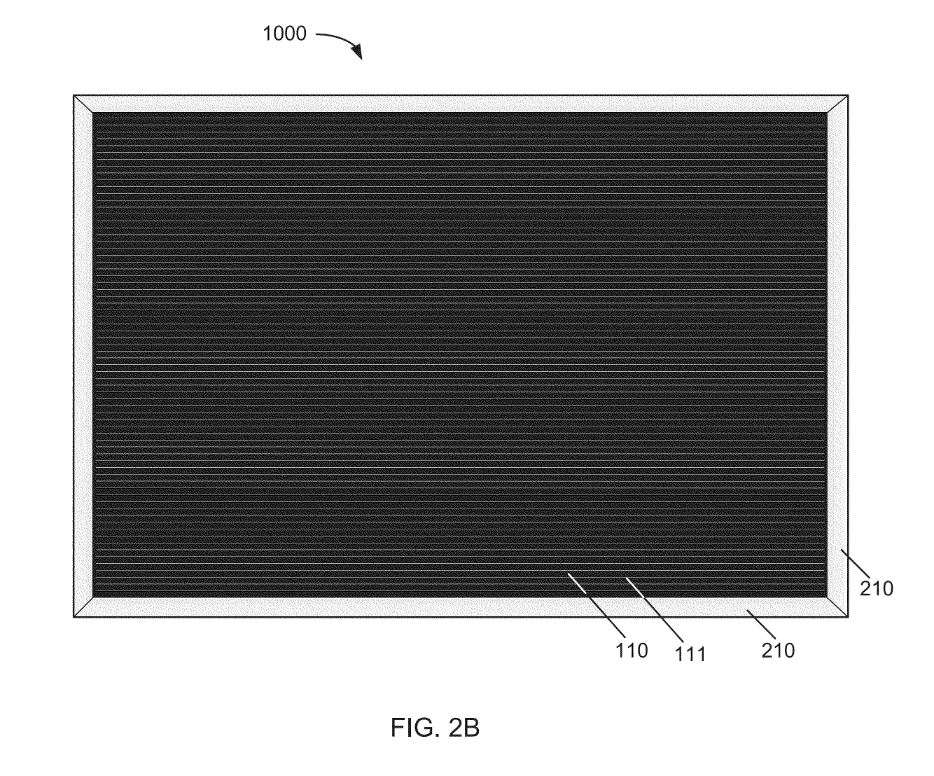

FIG. 2 is a simplified cross sectional diagram of a framed solar module with edge reflection enhancement according to an embodiment of the present invention. This diagram is merely an example, which should not unduly limit the scope of the claims herein. As shown, the framed solar module 1000 is monolithically integrated based on thin-film photovoltaic active material that formed on a glass substrate 100. In an example, the glass substrate 100 can have various sizes ranging from 6 inch square, 12 inch square, 20 inch square, and up to about 2 feet by 5 feet and even larger form factors. The thin-film photovoltaic material is configured to form a plurality of stripe-shaped cells 110 respectively divided by thin (nearly invisible) lines which include electrically conductive material for coupling all the cells. The material may be less than 1 mm in width, and may be in some embodiments about or less than 100 μm, 50 μm, 25 μm, 10 μm, 1 μm, 50 nm, 25 nm, 10 nm, or less. In a specific embodiment, the thin-film photovoltaic material in each cell includes a copper-based compound selectively containing sodium species, indium species, gallium species, selenium species, or sulfur species, although other types of photovoltaic active materials can be applied according to embodiments of this invention based on thin-film or crystallized silicon, poly-crystal silicon, silicon-germanium alloy, cadmium tellurium alloy, and more. The plurality of photovoltaic cells 110 are disposed to nearly entire surface area of the glass substrate 100, except vicinities of peripheral edge regions, where the frame 200 is wrapped around.

Within part of the peripheral edge regions and next to the plurality of photovoltaic cells 110, a conductor bus bar 120 is applied to form an electric coupler that couples the cells and provides a pair of electric leads (usually at bottom of the glass substrate 100, not shown) for the solar module 1000. Over the conductor bus bar 120, a mask tape 140 is applied for insulation purpose. Within rest part of the peripheral edge regions from the conductor bus bar (and the mask tape) to edges around the glass substrate 100, an edge seal material 130 is disposed for providing protection for the plurality of photovoltaic cells and associated electrical coupler from environment. In an embodiment, the mask tape 140 and the edge seal material 130 are respectively configured to be substantially reflective to cause any incoming light to scatter back instead of being absorbed.

In another embodiment, a transparent encapsulation material 150 is applied overlying the plurality of photovoltaic cells 110 and the mask tape 140. The encapsulation material 150 is used as a media for bonding a top glass panel 160. In a specific embodiment, the encapsulation material is selected from ethylene vinyl acetate, thermoplastic olefin, thermoplastic, or other transparent polymers, or some material that may protect the cells 110, while being substantially transparent so as to allow a majority of light to pass through the encapsulation material 150 to the cells 110. The top glass panel 160 is used as a cap member for a laminated solar module and has a substantially the same form factor as the glass substrate 100, for example, about 2 feet by 5 feet. In certain specific embodiment, the glass substrate 100 can be optionally attached with a tedlar layer as a protection material to complete lamination of a frameless solar module.

In yet another embodiment, the laminated solar module includes a reflector structure 210 disposed above the top glass panel 160 in vicinities of peripheral edge regions so that the sun light reaching therein can be reflected and re-directed at least partially to the middle region of the top glass panel and eventually being guided to the plurality of photovoltaic cells. In a specific implementation, the reflector structure 210 is part of a frame structure 200 used to wrap around the laminated solar module. As an example shown in FIG. 2, the reflector structure is an angled-surface 211 tilted above the top glass panel 160. An inner tilt angle 212 of the angled-surface 211 can be a few tens degrees or substantially greater so that the angled-surface 211 is configured to cause incoming light to be re-directed toward the nearby regions of the top glass panel. The surface may be angled at about 20 degrees or more, and may be angled at about or more than 30 degrees, 40 degrees, 50 degrees, 60 degrees, 70 degrees, 80 degrees, or more. In an embodiment, the angled-surface is not a mirror reflector, but instead a roughened surface so that incoming light is scattered and at least partially reaches to the photovoltaic active material to be converted to electric current, and indirectly enhancing the conversion efficiency of the assembled solar module 1000 by increasing the available light directed to the cells. Of course, there can be other variations, alternatives, and modifications. For example, the reflector structure 210 can be a member of a mounting rack for support a plurality of laminated solar modules. Each laminated solar module can be frameless or framed one and each reflector structure is clamped to part of the peripheral edge regions of both the top glass panel and the glass substrate (plus an optional tedlar). The mounting rack is configured to support each laminated solar module from the bottom of the glass substrate to form a solar module array. This type of solar module array is usually used with large scale in field as a solar energy production farm, but may also be used in residential and commercial rooftops, carports, and more.

FIG. 2A is a simplified diagram showing a top view off a monolithic thin-film solar module with an edge reflection-enhanced frame according to an embodiment of the present invention. This diagram is merely an example, which should not unduly limit the scope of the claims herein. One of ordinary skill in the art would recognize many variations, alternatives, and modifications. As shown, a monolithically integrated thin-film solar module 1000 is assembled with a frame that includes multiple reflector structures 210 disposed respectively along multiple edge regions. The top glass panel, when the module is exposed under the sun, is substantially transparent and configured to allow both directly illuminated sun light and substantial scattered light from the reflector structures to pass through and be guided to a plurality of photovoltaic cells 110 disposed below. In a specific embodiment, the plurality of photovoltaic cells is configured to be photon absorber and photovoltaic active so that photons are converted to electrons with high efficiency. As shown in FIG. 2B, the plurality of photovoltaic cells 110 appears dark due to good light absorption and occupies nearly entire surface region except peripheral edge regions. Also, each cell is formed in a stripe-shape divided with a neighboring cell by a thin (nearly invisible) line 111. In another specific embodiment, the peripheral edge region has about 1 inch or smaller in width for an integrated solar module with a form factor of 2 feet by 5 feet. For some other solar modules made by different cell structures made by either traditional silicon-based cells or thin-film photovoltaic absorber based cells, this edge reflection enhancement approach translates to a roughly 5-20% of total module surface area due to the increased performance. Traditionally, these areas are not being actively used for solar energy production if the conductor bus bars are covered by dark colored mask tape, the peripheral edge regions is sealed by an edge seal material without being characterized to have high reflectivity, or fully covered by a non-transparent frame structures. In other words, the embodiments of the present invention in principle would help to enhance module efficiency by directing light illuminated on the peripheral edge region toward the photovoltaic active region to effectively increase photovoltaic active area up to 5-20% for the solar module, although only part of the scattered light from the reflector structure may be utilized. Of course, there are many other variations, alternatives, and modifications.

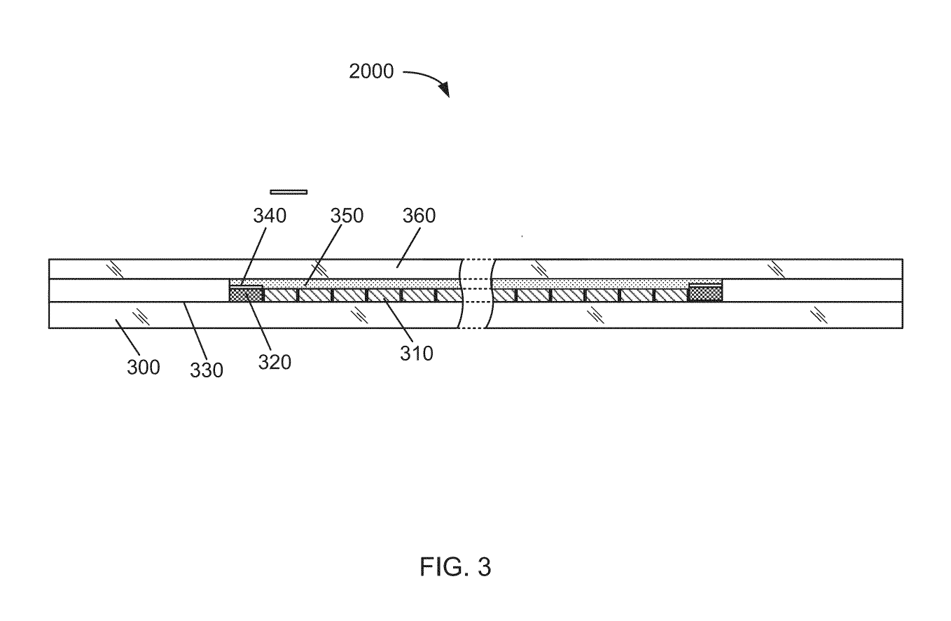

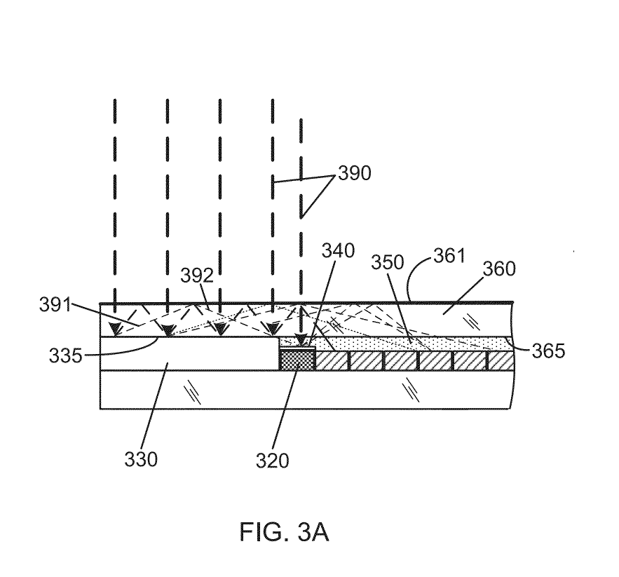

In an alternative embodiment, a laminated solar module without any reflector structure is provided with edge reflection enhancement. FIG. 3 is a simplified cross sectional diagram of a frameless solar module with edge reflection enhancement according to an embodiment of the present invention. This diagram is merely an example, which should not unduly limit the scope of the claims herein. One of ordinary skill in the art would recognize many variations, alternatives, and modifications. As shown the laminated solar module 2000 may include a plurality of photovoltaic cells 310 formed on a glass substrate 300 and capped by a top glass panel 360 without a frame to wrap around. Additionally, within peripheral edge regions of the glass substrate 300, there is a photovoltaic inactive area containing a conductor bus bar 320 covered by a mask tape 340 and sealed by an edge seal material 330. The top glass panel 360 is bonded with an transparent encapsulation material 350 applied overlying the plurality of photovoltaic cells 310 as well as mask tape 340 within part of the peripheral edge regions.

In a specific embodiment, the frameless solar module 2000 is applied with a white-colored mask tape 340 and an edge seal material 330 being configured to cause incoming sun light to scatter back without being substantially absorbed. The scattered light mostly is reflected back toward the top glass panel. FIG. 3A is a simplified diagram illustrating exemplary edge reflection of the frameless solar module in FIG. 3 according to an embodiment of the present invention. As shown as an example, sun light 390 is illuminated to the peripheral edge region from above the top glass panel 360. Firstly, the top glass panel 360 includes a surface coating 361 that is configured to enhance sun light transmission and reduce reflection substantially. The light further passes through the transparent encapsulation material 350 to reach the mask tape 340. The light passes through the top glass panel and reaches the edge seal material 330, directly. Both the top surface of the mask tape 340 and edge seal material 330 (or at least an interface 335 between the edge seal material 330 and the encapsulation material 350 are configured to cause the incoming sun light to scatter upward in multiple directions. Of course, the incoming sun light also comes from various angles, although only the light 390 with vertically incident angle is illustrated as an example.

Referring to FIG. 3A, in an embodiment, a first plurality of scattered lights 391 from the interface 335 may pass through an interface 365 between the encapsulation material 350 and the top glass panel to reach the surface coating 361 from inner side with multiple incident angles. The surface coating 361 is also configured to enhance reflection of the first plurality of scattered lights illuminated from inner side, thereby redirecting the scattered lights downward (in multiple angles). Within the peripheral edge regions, the inner reflections of the scattered lights 391 occur multiple times before guiding the lights partially to reach the photovoltaic active region. In an implementation, the edge seal material is a butyl rubber, ethylene vinyl acetate, thermoplastic olefin, thermoplastic, or other transparent or non-transparent polymers or rubbers. The surface coating 361 overlying the top glass panel includes an applied coating (e.g. magnesium fluoride or quartz) or mechanical structuring/texturing of the glass (e.g. prismatic) which is configured to provide the unique optical transmission and reflection properties for lights respectively illuminated from up side and down side. In another embodiment, a second plurality of scattered lights 392 from the interface 335 with multiple incident angles may be reflected by the interface 365 and multiple inner reflections also occur before the second plurality of scattered lights being partially guided to the photovoltaic active region. The mask tape 340 is also configured to cause the inner reflections of incoming light. For example, a simple white colored mask tape may be used to cause the multiple inner reflections of the incoming light in a similar fashion described above for edge seal material 330. The tape may alternatively be of different colors including having more of a mirror-like reflective surface.

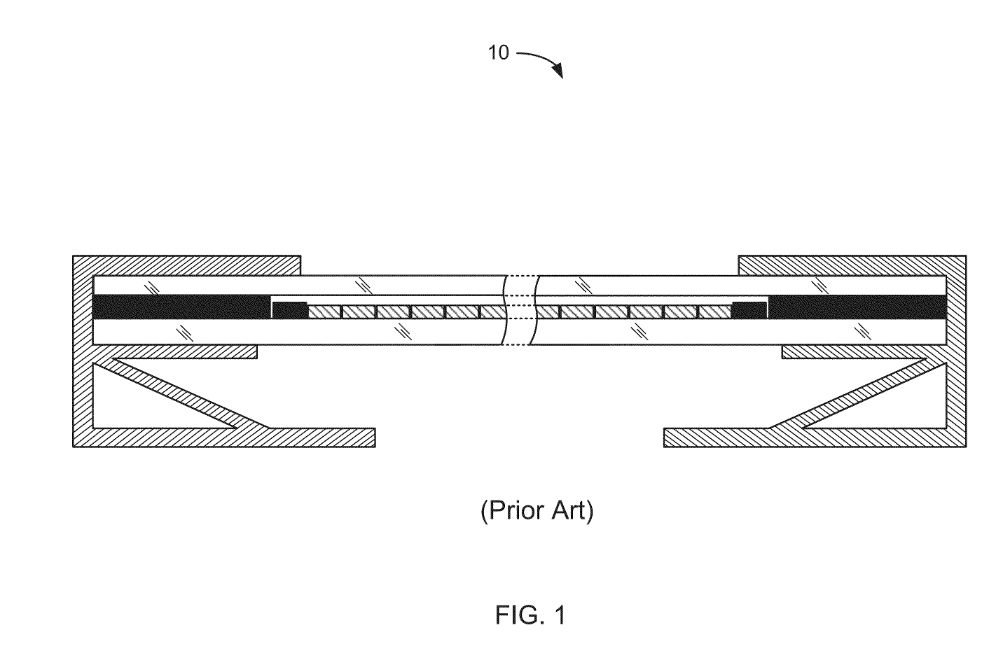

In yet another alternative embodiment, the laminated solar modules with edge reflection enhancement can be mounted one next to another to form a solar module array for various solar energy production applications. In an implementation, the framed solar modules 1000 with angled-surface member configured with the frame structure wrapped around the peripheral edge regions, as shown in FIG. 1, can be mounting one next to another on rail structures. The frame structure is utilized to couple with the rail structure accordingly. The angled-surface member at the one edge of a solar module is attached with another angled-surface member at another edge of a neighboring solar module without any incompatibility with existing mounting rail structures for regular framed solar modules. In another implementation, the frameless solar modules can be supported on a mounting rack from one or more positions at the back side of the module (i.e., the bottom side of the glass substrate or a tedlar layer attached with the substrate) with optional partial edge clamping. The frameless laminated solar module 2000 with inner edge refection enhancement, as shown in FIG. 2, 2A, 2B, can be used in this type of deployment for large area solar energy farm in wild field. Additional reflector structure can be added to the boundary area between neighboring modules.

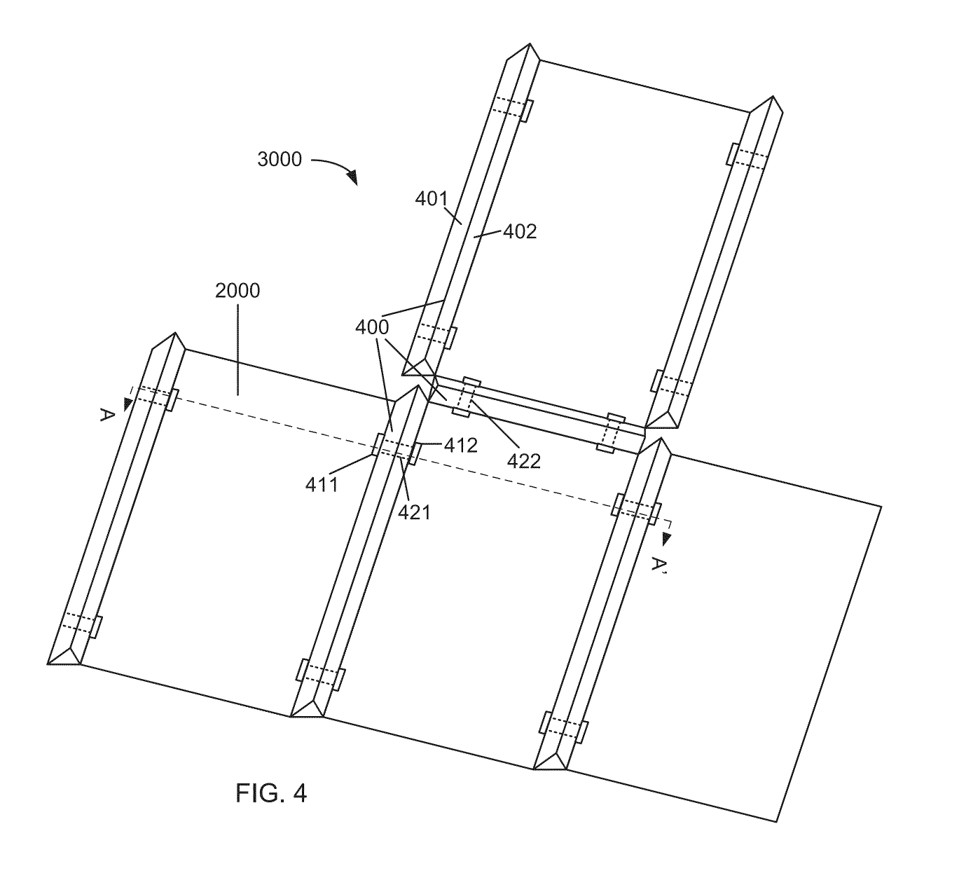

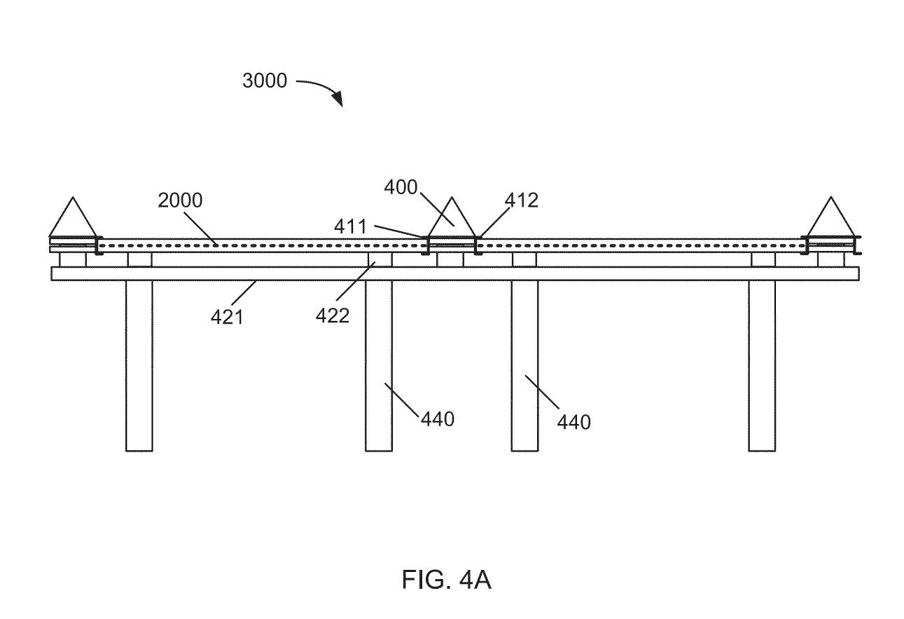

FIG. 4 is a schematic diagram of a solar module array with edge reflection enhancement according to an embodiment of the present invention. This diagram is merely an example, which should not unduly limit the scope of the claims herein. One of ordinary skill in the art would recognize many variations, alternatives, and modifications. As shown, a solar module array 3000 is assembled by mounting each of a plurality of frameless solar modules 2000 respectively on one or more crossed bars 421 and 422 of a mounting rack system. In an embodiment, the cross bars 421 and 422 include a few clamping elements 411 and 412 located within a boundary region between each pair of solar modules. Several clamping elements together are used to fix the solar module with the cross bars (or the mounting rack system). Provided a spacing of each boundary region, one reflector structure 400 with at least two angled surfaces 401 and 402 can be added and attached to one or two clamping elements disposed in the same boundary region. In an example, the reflector structure 400 is a three-face prism with one face being attached to the clamping elements 411 and 412 and two other faces being configured to re-direct incoming light from the boundary region respectively toward two neighboring modules and at least partially to reach photovoltaic active area for solar energy production. The reflector structure 400 can be made by low cost sheet material with white colored paint to fulfill its function for enhancing light scattering and redirecting incoming sun light towards the module surfaces from the boundary regions, effectively enhancing photovoltaic active area of the solar module array 3000. For a rectangular shaped solar module, each has four boundary regions ready for installing four reflector structures respectively. For small area roof top installation, framed solar modules with angled-surface members are applied so that no such additional reflector structure is necessary.

FIG. 4A is an AA′ cross-sectional view of the solar module array in FIG. 4 according to an embodiment of the present invention. This diagram is merely an example, which should not unduly limit the scope of the claims herein. One of ordinary skill in the art would recognize many variations, alternatives, and modifications. In this cross sectional view, each solar module is shown to have two glass panels and at a photovoltaic active material being sandwiched by the two glass panels and is substantially the same as the frameless solar module 2000. In an embodiment, the solar module itself can have reflective edge seal material and mask tape applied within its peripheral edge region for edge light reflection enhancement. In another embodiment, additional reflector structures 400 are installed within a boundary region between any two solar modules in the array. In this cross sectional view, the reflector structure is schematically a triangle shaped device having two angled surfaces for scattering incoming light respectively to the photovoltaic active areas of corresponding solar modules to the left side and right side. In an implementation, the reflector structure can be made by a low cost sheet material having white colored paint on the angled surfaces facilitating the light scattering. Both the laminated solar modules 2000 and the reflector structures 400 in between are configured to be mounted on one or more cross bars 421 and 422 coupled to the mounting rack system 440. Additionally, some clamp elements 411 and 412 are used to fix the reflector structure 400 with the laminated solar modules on their edge regions. Of course, there are many variations, alternatives, and modifications.

It is also understood that the examples and embodiments described herein are for illustrative purposes only and that various modifications or changes in light thereof will be suggested to persons skilled in the art and are to be included within the spirit and purview of this application and scope of the appended claims. Further details of a specific method for a solar module lamination and assembly with edge reflection enhancement can be found throughout the present specification and more particularly below.

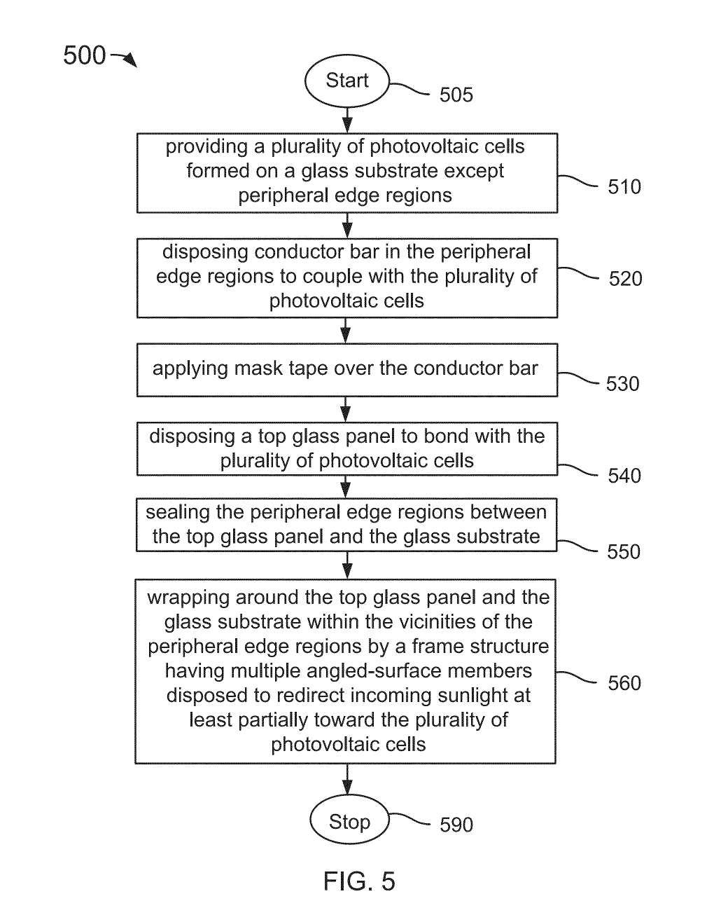

FIG. 5 is a schematic flowchart illustrating a method for making a solar module with edge reflection enhancement according to an embodiment of the present invention. This diagram is merely an example, which should not unduly limit the scope of the claims herein. One of ordinary skill in the art would recognize other variations, modifications, and alternatives. It is also understood that the examples and embodiments described herein are for illustrative purposes only and that various modifications or changes in light thereof will be suggested to persons skilled in the art and are to be included within the spirit and purview of this process and scope of the appended claims.

As shown in FIG. 5, the present method 500 can be briefly outlined below.
1. Start (505);
2. Process 510 for providing a plurality of photovoltaic cells formed on a glass substrate except vicinities of peripheral edge regions;
3. Process 520 for disposing conductor bar in the peripheral edge regions to couple with the plurality of photovoltaic cells;
4. Process 530 for applying mask tape over the conductor bar;
5. Process 540 for disposing a top glass panel to bond with the plurality of photovoltaic cells;
6. Process 550 for sealing the peripheral edge regions between the top glass panel and the glass substrate;
7. Process 560 for wrapping around the top glass panel and the glass substrate within the vicinities of the peripheral edge regions by a frame structure having multiple angled-surface members disposed to redirect incoming sunlight at least partially toward the plurality of photovoltaic cells;
8. Stop (590).

The above sequence of processes provides a method of manufacturing a monolithically integrated solar module with edge reflection enhancement according to an embodiment of the present invention. In a preferred embodiment, process for solar module lamination includes forming a plurality of photovoltaic cells overlying main surface regions of a glass substrate followed by sealing peripheral edge regions. In another preferred embodiment, after capping with a top glass panel, a frame structure with angled surface members is applied to wrap around the peripheral edge regions of both the glass substrate and the top glass panel. The angled surface members are configured to redirect incoming light at least partially toward the main surface regions with the photovoltaic cells so that the effective photovoltaic active area is increased. Other alternatives can also be provided where certain processes are added, one or more processes are removed, or one or more processes are provided in a different sequence without departing from the scope of the claims herein. Further details of the method can be found throughout the present specification and more particularly below.

As shown in FIG. 5, the method 500 begins at start, step 505. In a specific embodiment, the method 500 is last part of a series of processes for manufacturing monolithic thin-film photovoltaic modules, for example, the solar module 1000 as seen in FIG. 2. At Process 510, a plurality of photovoltaic cells is provided. In particular, the plurality of photovoltaic cells is based on a thin-film photovoltaic absorber material containing a copper-indium-gallium-selenium compound that is formed on a soda lime glass substrate having a form factor of 2 feet by 5 feet or greater. Of course, the method according to the present invention does not limit its claims to a specific substrate form factor and material type used for the manufacture of the photovoltaic module. This process includes formation of thin-film structures including one or more barrier materials, a bottom electrode, and several precursor materials containing copper, sodium, indium and/or gallium species. This process also includes formation of several patterning structures to define the cells and cell-cell coupling configurations. This process further includes one or more reactive thermal treatment of the precursor materials within a gaseous selenium and/or sulfur environment to transform the precursor materials into a thin-film photovoltaic absorber material comprising CIGS/CIGSS compound. Furthermore, this process includes forming a top electrode and patterning the plurality of photovoltaic cells to pin-stripe shaped cells along a length direction of the substrate, as seen in FIG. 2B, respectively divided by many thin (nearly invisible) conductive lines configured to couple each cell electrically to both the bottom electrode and the top electrode. More details can be found in U.S. Pat. No. 7,910,399 titled “THERMAL MANAGEMENT AND METHOD FOR LARGE SCALE PROCESSING OF CIS AND/OR CIGS BASED THIN FILMS OVERLYING GLASS SUBSTRATES” issued in Mar. 22, 2011, assigned to Stion Corporation, California, incorporated as references for all purposes. In one or more embodiments, the plurality of photovoltaic cells is formed substantially overlying entire surface region of the glass substrate except vicinities of peripheral edge regions.

In the Process 520, one or more conductor bars are disposed in the peripheral edge regions to couple with the plurality of photovoltaic cells. Within each side of the glass substrate along the peripheral edge regions, a conductor bus bar is firstly disposed next to the plurality of photovoltaic cells and is configured to couple each cell via either the bottom electrode or the top electrode. Each conductor bus bar occupies an inner portion of the peripheral edge regions (see FIG. 2). The conductor bus bar, in a specific embodiment, can be guided through the glass substrate to provide a pair of electric leads at the bottom side of the module, although some details like the electrodes and coupling configuration of the conductor bus bar with the electrodes as well as electric leads for the solar module are not explicitly illustrated in the drawings of this specification. The conductor bus bar is made by a high conductivity metal material selected from copper, silver, or gold. The coupling between the conductor bus bar and the electrodes can use soldering or other technology.

In the process 530, a mask tape is further applied over the top of each of the one or more conductor bus bars to insulate it from the rest part of the peripheral edge regions and the photovoltaic active region. In a specific embodiment, the process 530 includes selecting a white colored mask tape that is configured to enhance light scattering instead of absorption. As incoming sun light illuminates over the peripheral edge regions of a framed (or frameless) solar module, the light would be scattered at least partially from the mask tape. Especially for a frameless solar module, more sun light may be scattered back from the regions covered by the white colored mask tape and the scattered light is likely to be re-directed via inner reflection to the photovoltaic active region in the vicinity of the conductor bus bar.

Furthermore, the method 500 includes a process 540 for disposing a top glass panel to bond with the plurality of photovoltaic cells. In an embodiment, the process includes applying an encapsulation material overlying the plurality of photovoltaic cells (over the top electrode) and the mask tapes around part of the peripheral edge regions. The encapsulation material, in an embodiment, is partly to ensure substantial transmission of electromagnetic radiations (especially within a spectrum of visible light) coming from the sun through the top glass panel and partly to serve as a bonding material for the lamination of the solar module. The encapsulation material is selected from ethylene vinyl acetate, thermoplastic olefin, thermoplastic, or other transparent polymers characterized by an optical transparency of >90% and a good electrical insulator. The top glass panel, selected to have a substantially same form factor of the glass substrate, thus forms a top cap for the laminated solar module and serves a top-most structure element exposing to the sun light when the solar module is in its deployment position. In a specific embodiment, the process 540 also includes a step of processing surface of the top glass panel to provide desired optical characteristics.

In particular, a surface coating (e.g. magnesium fluoride or quartz) or mechanical structuring/texturing of the glass (e.g. prismatic) are applied to enhance transmission for the incident light from above and reflectivity for the scattered light from below. The higher the transmission of incoming sun light certainly is desired for delivering more photons to the photovoltaic active regions. For a portion of the incident light that reaches the peripheral edge regions, at least partially, the light is scattered back from the mask tape or material in the vicinity and may reach the surface coating of the top glass panel. The higher the reflection of the scattered light from below by the surface coating, the more photons can be transferred to the photovoltaic active regions.

Next process 550 includes applying an edge seal material to the rest portion of the peripheral edge regions between the top glass panel and the bottom glass substrate. In an embodiment, the edge seal material is to protect the plurality of photovoltaic cells and the associated electric circuits (including the conductor bus bar and its coupling configuration with each cell). In a specific embodiment, the edge seal material is an insulation material selected from a butyl rubber, ethylene vinyl acetate, thermoplastic olefin, thermoplastic, or other transparent or non-transparent polymers or rubbers, characterized by its property of chemically inert and physical density for preventing environmental caused corrosion and device degradation. In another specific embodiment, the process 550 includes characterizing the edge seal material to have an enhanced reflectivity to incoming light, in particular for lights within visible spectrum range. As incoming sun light illuminates over the peripheral edge region, especially for a frameless solar module, major portion of the incoming sun light may be scattered back from either the mask tape or the edge seal material itself and at least partially is able to be re-directed towards the photovoltaic active regions, effectively enhancing solar energy production efficiency by increasing the photovoltaic active area.

Referring to FIG. 5 again, the method 500 further includes a process, 560, for wrapping around the top glass panel and the glass substrate within the vicinities of the peripheral edge regions by a frame structure having multiple angled-surface members disposed to redirect incoming sunlight at least partially toward the plurality of photovoltaic cells. As an example shown in FIG. 2, the process 560 is for manufacturing a monolithically framed solar module with edge reflection enhancement. In a specific embodiment, the frame structure replaces a regular flat piece that caps the top edge of the top glass panel by a triangular shaped piece having an angled surface facing down the top glass panel from a higher edge of the frame. The angled surface is configured to facilitate scattering of lights from there toward the central portion of the top glass panel in multiple angles. In an embodiment, a single surface painted by white color paint is deployed. In another embodiment, a combination of multi-angled surfaces with a substantial high reflectivity for each surface is deployed. In yet another embodiment, the frame structure may include a transparent flat piece to cap the top edge to allow the incoming light to directly reach the reflective edge seal material and a white mask tape within the peripheral edge regions to enhance edge reflection internally. Of course, there are many variations, alternatives, and modifications.

The method 500 stops at process 590. Of course, there are many other variations, alternatives, and modifications. For example, the reflector structure may be an element separated from a frame structure that is only clamped to the peripheral edge regions at a couple of points. Using the example shown in FIG. 2, 2A, and FIG. 2B, the peripheral edge regions takes about 5-20% of surface area of the laminated solar module. The method 500 according to the present invention at least partially turns this portion of wasted surface area to an effective photovoltaic active area, thereby enhancing solar energy conversion efficiency of the solar module.

Although the above has been illustrated according to specific embodiments, there can be other modifications, alternatives, and variations. It is understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A monolithically integrated solar module with edge reflection enhancement, the solar module comprising:
a plurality of thin-film photovoltaic cells formed overlying a surface region of a glass substrate except vicinities of peripheral edge regions;
a mask tape applied on a conductor bar disposed within the peripheral edge regions and coupled with the plurality of thin-film photovoltaic cells;
an edge seal material disposed within the peripheral edge regions in a vicinity of the mask tape and an end region of the glass substrate;
a top glass panel disposed overlying the plurality of thin-film photovoltaic cells, the mask tape, and the edge seal material; and
a reflector structure comprising one or more angled surfaces each being configured to facilitate scattering of incoming sunlight from the vicinities of the peripheral edge regions partially to the plurality of thin-film photovoltaic cells.

2. The solar module of claim 1 wherein the plurality of thin-film photovoltaic cells comprises stripe-shaped cells separated by substantially invisible cell lines, each cell including a thin-film absorber compound material made from copper species, indium species, gallium species, selenium species, sulfur species, and sodium species.

3. The solar module of claim 1 wherein the conductor bar is placed on an upper side of the glass substrate for electrically coupling with the plurality of thin-film photovoltaic cells and the method further includes providing a pair of electric leads for the solar module to a bottom side of the glass substrate.

4. The solar module of claim 1 wherein the mask tape comprises a white colored surface for turning incoming sunlight into scattered light partially toward the top glass panel.

5. The solar module of claim 4 wherein the top glass panel comprises a top surface and a bottom surface, the top surface being coated and/or patterned to enhance inner reflection of the scattered light being re-directed toward the plurality of thin-film photovoltaic cells; the bottom surface being bonded with the plurality of thin-film photovoltaic cells, the mask tape, and the edge seal material and configured to re-direct the scattered light at least partially back to the plurality of thin-film photovoltaic cells.

6. The solar module of claim 1 wherein the edge seal material comprises an optical characteristic for scattering incoming sunlight back to the top glass panel before being at least partially redirected towards the plurality of thin-film photovoltaic cells.

7. The solar module of claim 1 wherein the reflector structure is a member of a frame structure assembled to monolithically integrate the top glass panel and the glass substrate together along the peripheral edge regions.

8. The solar module of claim 1 wherein the reflector structure is a member of mounting rack for assembling one or more solar modules into an array, the reflector structure being disposed along the peripheral edge regions of each solar module.

9. A solar module with reflection enhancement on frameless edge regions, the solar module comprising:
a plurality of photovoltaic cells formed overlying a surface region of a glass substrate except in vicinities of peripheral edge regions;
a mask tape applied on a conductor bar disposed within the peripheral edge regions and coupled with one or more of the plurality of photovoltaic cells;
a top glass panel disposed overlying the plurality of photovoltaic cells and the mask tape via an encapsulation material; and
an edge seal material disposed between the top glass panel and the glass substrate within the peripheral edge regions, the edge seal material being configured with the mask tape to cause incoming sunlight substantially being scattered away from the peripheral edge regions and re-directed at least partially toward the plurality of photovoltaic cells.

10. The solar module of claim 9 wherein the plurality of photovoltaic cells comprises one photovoltaic absorber selected from a copper-based thin-film absorber, a silicon-based thin-film absorber, a single crystal silicon absorber, a polycystal silicon absorber, and an amorphous silicon absorber.

11. The solar module of claim 9 wherein the conductor bar is placed on an upper side of the glass substrate for electrically coupling with the plurality of thin-film photovoltaic cells and providing a pair of electric leads for the solar module to a bottom side of the bottom glass substrate.

12. The solar module of claim 9 wherein the mask tape comprises a white-colored surface for scattering incoming sunlight at least partially towards the plurality of photovoltaic cells directly or indirectly through reflections by the top glass panel.

13. The solar module of claim 9 wherein the edge seal material comprises an optical property characterized by a reflectivity for substantially scattering part of incoming sunlight in the peripheral edge region back to the top glass panel which further directs the part of sunlight at least partially toward the plurality of photovoltaic cells.

14. The solar module of claim 9 further comprising:
one or more reflector structures as members of a mounting rack for assembling one or more solar modules into an array; and
one or more reflector structures disposed in boundary regions of the one or more solar modules, the one or more reflector structures being configured to re-direct incoming sunlight from the boundary regions at least partially toward the plurality of photovoltaic cells in the one or more solar modules.

15. A method for solar module lamination with enhanced edge reflection, the method comprising:
providing a plurality of photovoltaic cells formed overlying substantially a surface region of a glass substrate except of peripheral edge regions;
disposing one or more conductor bars next to the plurality of photovoltaic cells within the peripheral edge regions;
applying one or more mask tapes over the one or more conductor bars;
disposing a top glass panel having a surface characteristic with an enhanced transmission of light from above and an enhanced reflection of light below to bond with the plurality of photovoltaic cells;
sealing the peripheral edge regions between the top glass panel and the glass substrate; and
wrapping around the top glass panel and the glass substrate within the vicinities of the peripheral edge regions by a frame structure having multiple angled-surface members, the angled-surface members being configured to redirect incoming sunlight at least partially from the peripheral edge regions toward the plurality of photovoltaic cells.

16. The method of claim 15 wherein the providing the plurality of photovoltaic cells comprising coupling the plurality of photovoltaic cells respectively to a top electrode and a bottom electrode.

17. The method of claim 16 wherein the disposing one or more conductor bars comprising coupling the one or more conductor bars respectively to the top electrode and the bottom electrode of the plurality of photovoltaic cells.

18. The method of claim 15 wherein the sealing the peripheral edge regions comprises applying an edge seal material selected from a butyl rubber, ethylene vinyl acetate, thermoplastic olefin, thermoplastic, or other transparent or non-transparent polymers or rubbers.

19. The method of claim 15 wherein the multiple angled-surface members comprise a white-colored paint thereon for facilitating redirections of incoming sunlight at least partially toward the plurality of photovoltaic cells.

20. The method of claim 15 wherein the plurality of photovoltaic cells comprises one photovoltaic absorber selected from a copper-based thin-film absorber, a silicon-based thin-film absorber, a single crystal silicon absorber, a polycystal silicon absorber, and an amorphous silicon absorber.
